(19) United States
(12) Patent Application Publication
(10) Pub. No.: US 2026/0304987 A1
(43) Pub. Date: Oct. 1, 2026

(54) IMAGING INTEGRATED CIRCUIT DEVICE AND METHOD OF FABRICATING THE SAME

(71) Applicant: Taiwan Semiconductor Manufacturing Company, Ltd., Hsinchu (TW)

(72) Inventors: Yi-Hsuan Wang, Hsinchu City (TW); Cheng-Yu Huang, Hsinchu (TW); Keng-Yu Chou, Kaohsiung City (TW); Wei-Chieh Chiang, Yuanlin Township (TW); Chun-Hao Chuang, Hsinchu City (TW)

(21) Appl. No.: 19/089,445

(22) Filed: Mar. 25, 2025

(51) Int. Cl. H10F 39/00; H10F 39/18

(52) U.S. Cl. CPC H10F 39/807; H10F 39/014; H10F 39/182

(57) ABSTRACT

Some embodiments relate to an integrated circuit (IC) device including a substrate having a plurality of first photosensitive regions and a plurality of second photosensitive regions. Each of a plurality of first photosensitive region groups includes one or more first photosensitive regions and is associated with one of a plurality of image pixels, and each second photosensitive region group includes one or more second photosensitive regions and is associated with one of a plurality of phase detection pixels. The IC device also includes an isolation structure extending toward a first side of the substrate from a second side of the substrate. The isolation structure circumscribes each of the first photosensitive regions in a plan view of the IC device. The isolation structure includes a first configuration for each image pixel and a second configuration different from the first configuration for each phase detection pixel in the plan view.

### BACKGROUND

Some integrated circuit (IC) manufacturers have integrated aspects of phase detection auto-focus (PDAF) technology in complementary metal-oxide-semiconductor (CMOS) image sensor (CIS) devices. In such devices, the speed associated with PDAF technology may be higher than that associated with other auto-focus technologies, as the device may provide the phase detection data needed for auto-focus functionality on a continual basis with little latency while simultaneously capturing image data.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIGS. 1A through 1D illustrate a plan view, a cross-sectional view, an alternative cross-sectional view, and an additional cross-sectional view, respectively, of some embodiments of an integrated circuit (IC) device employing an isolation structure providing reduced crosstalk for half-shield PDAF, according to the present disclosure.

FIGS. 2 through 12 illustrate plan views of some additional embodiments of an IC device employing an isolation structure providing reduced crosstalk for half-shield PDAF, according to the present disclosure.

FIGS. 13A through 13C illustrate a plan view, a cross-sectional view, and an alternative cross-sectional view, respectively, of some embodiments of an IC device employing an optical lens layer providing reduced crosstalk for half-shield PDAF, according to the present disclosure.

FIG. 13D illustrates a cross-sectional view of some embodiments of an IC device employing an isolation structure and an optical lens layer providing reduced crosstalk for half-shield PDAF, according to the present disclosure.

FIGS. 14 through 16 illustrate plan views of some additional embodiments of an IC device employing an optical lens layer providing reduced crosstalk for half-shield PDAF, according to the present disclosure.

FIGS. 17A through 17L illustrate cross-sectional views of some embodiments of an IC device employing an isolation structure providing reduced crosstalk for half-shield PDAF, as shown in FIG. 1C, at various stages of manufacture, according to the present disclosure.

FIG. 18 illustrates a block diagram of some embodiments of a methodology of forming an IC device employing an isolation structure providing reduced crosstalk for half-shield PDAF, according to the present disclosure.

FIGS. 19A and 19B illustrate cross-sectional views of some embodiments of an IC device employing an optical lens layer providing reduced crosstalk for half-shield PDAF, as shown in FIG. 13C, at various stages of manufacture, according to the present disclosure.

FIG. 20 illustrates a block diagram of some embodiments of a methodology of forming an IC device employing an optical lens layer providing reduced crosstalk for half-shield PDAF, according to the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

In some cases, phase detection auto-focus (PDAF) functionality may be incorporated in a complementary metal-oxide-semiconductor (CMOS) image sensor (CIS) integrated circuit (IC) device by way of a half-shield phase detection (HSPD) pixel design. In such a design, some pixel locations of an image pixel array are occupied by special-purpose phase detection pixels that incorporate a “half-shield” disposed over a portion (e.g., a left half, a right half, a bottom half, or a top half) of the associated pixel, thus substantially blocking light from half of the one or more photodetectors associated with the pixel. Processing the data from such phase detection pixels may produce an indication (e.g., a magnitude and direction) by which a relative distance between an external lens (e.g., a camera lens) and the CIS IC device may be altered to bring an object into focus on the CIS IC device. In some cases, an HSPD pixel arrangement may serve as the primary phase detection mechanism for the CIS IC device, while in other examples, an HSPD pixel arrangement may be employed during time periods when another phase detection mechanism (e.g., a quadrature phase detection (QPD) PDAF circuit employing the image pixels) is unavailable, such as during QPD four-cell (4 C) binning.

However, in some HSPD designs, a portion of light encountering an HSPD pixel may be improperly directed to a neighboring image pixel, such as by way of one or more isolation structures (e.g., a backside deep trench isolation (BDTI) structure) that may surround each of multiple photosensitive regions of the phase detection pixel. More specifically, such a bottom side or surface of such an isolation structure may cause light scattering that redirects the received light toward an adjacent image pixel, thereby possibly increasing the amount of light detected by the image pixel beyond the amount actually associated with that pixel.

In some cases, such crosstalk between HSPD pixels and image pixels may be optimized by the use of an overlying grid structure (e.g., a metal grid (MG)) structure with segments having a width with a critical dimension (CD) that maintains a same sensitivity for the HSPD pixels and the image pixels in the presence of scattering caused by the isolation structure, as discussed above. However, this sensitivity balancing may lead to a shift in the spectral response or quantum efficiency (QE) (e.g., the portion of photon flux that may contributed to the photocurrent associated with a pixel) relative to the wavelength of light being received by the HSPD pixel relative to an image pixel. Consequently, the combination of the isolation structure and the grid structure may cause a decrease in QE at lower optical wavelengths (e.g., due to the width CD of the segments of the grid structure) and an increase in QE at higher optical wavelengths (e.g., caused by BDTI light scattering).

To address these issues, the present disclosure provides some embodiments of an IC device that employs either or both of an isolation structure and an optical lens layer configured to reduce the scattering of light from an HSPD pixel to a neighboring image pixel. In some embodiments, the isolation structure, while surrounding each photosensitive region of the image pixels, may have an altered (e.g., reduced) structure in one or more of the phase detection pixels. For example, in some embodiments, the isolation structure may include a different configuration in a phase detection pixel than for the image pixels in a plan view of the IC device. In other embodiments, the optical lens layer may include a lens portion (e.g., a spherical lens portion) over each photosensitive region group associated with an image pixel, and may also include at least two lens portions (e.g., multiple elliptical lens portions, or multiple spherical lens portions that are smaller than the lens portions associated with the image pixels) over each photosensitive region group associated with an HSPD pixel. Use of such isolation structures and/or optical lens layers may reduce the amount of light redirected to a neighboring image pixel by an HSPD pixel. Consequently, potential issues caused by such crosstalk, such as undesirable flaring associated with image pixels dues to uneven light sensitivity between image pixels and HSPD pixels, QE shift within HSPD pixels, and so on, may be mitigated.

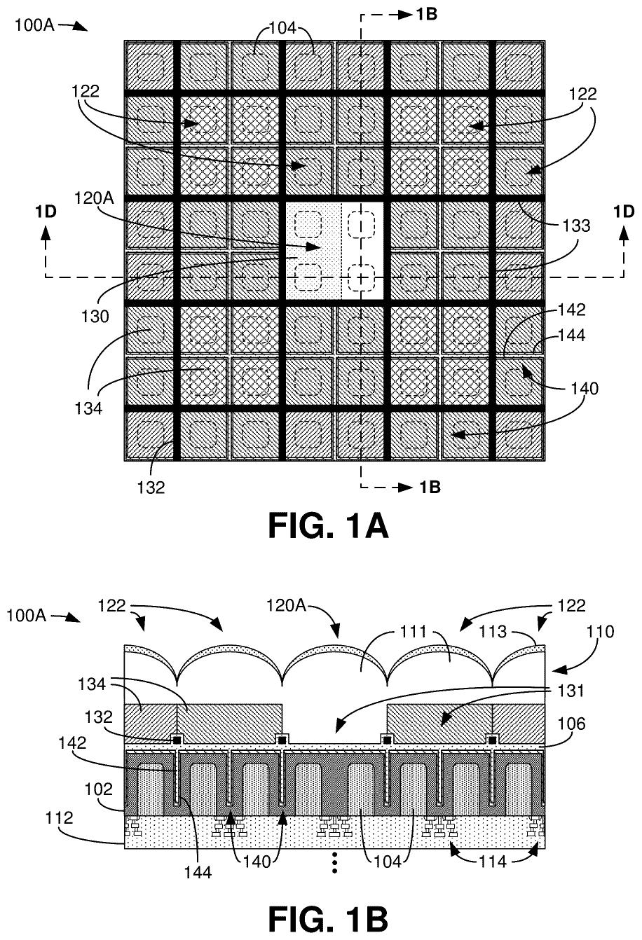

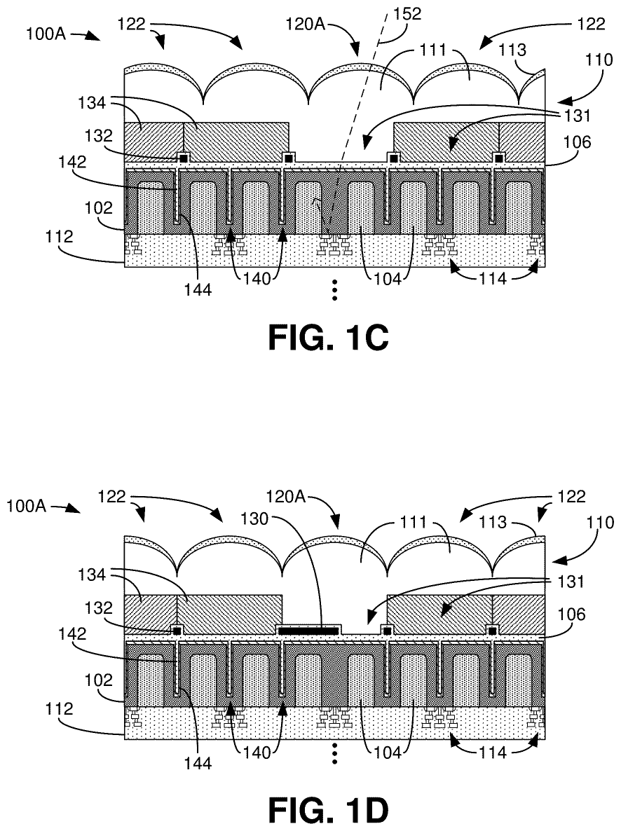

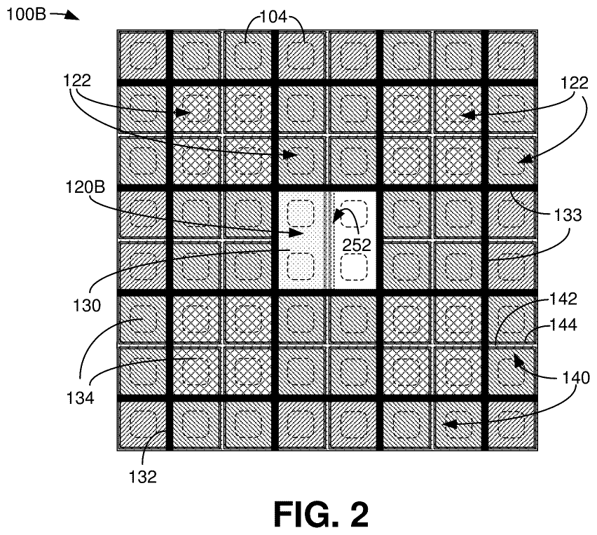

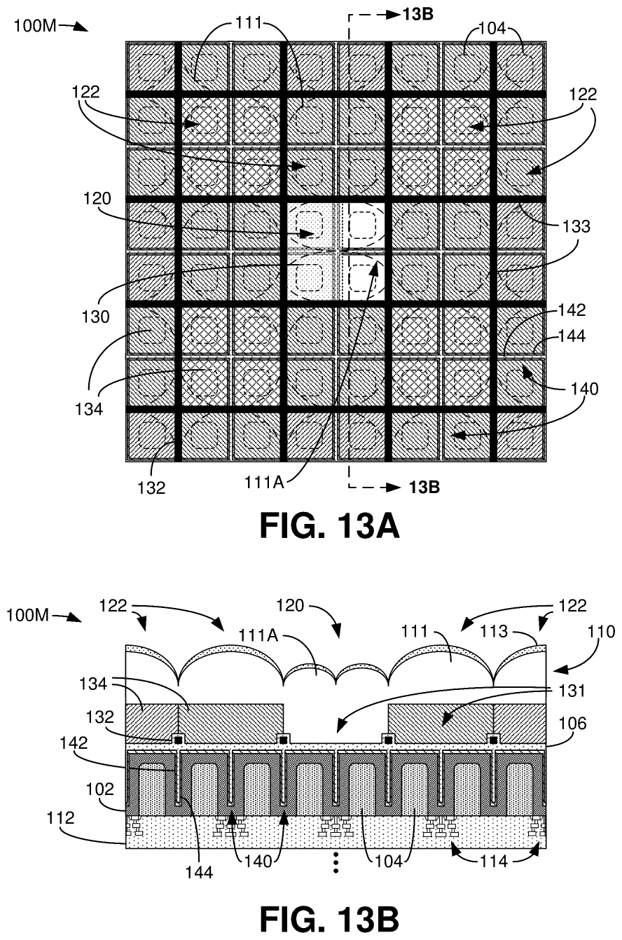

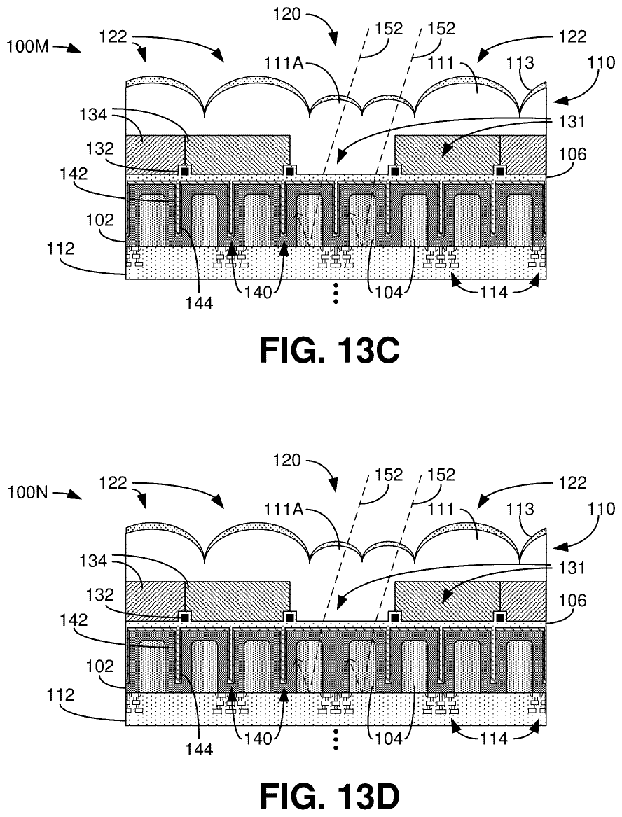

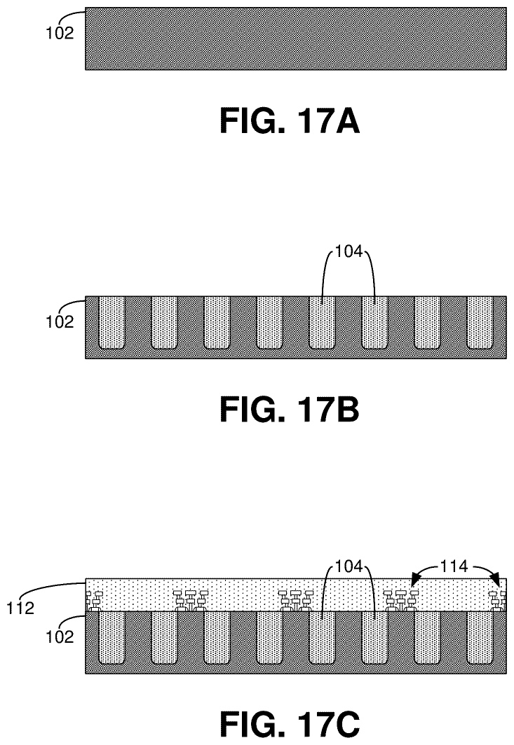

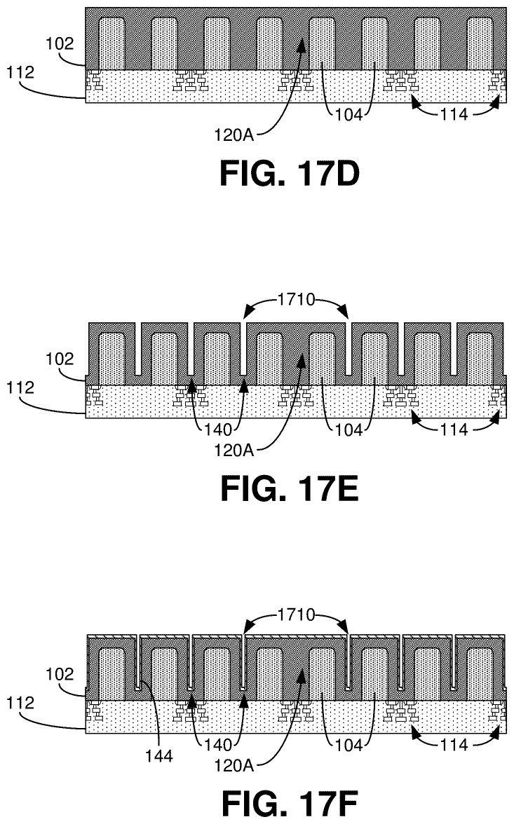

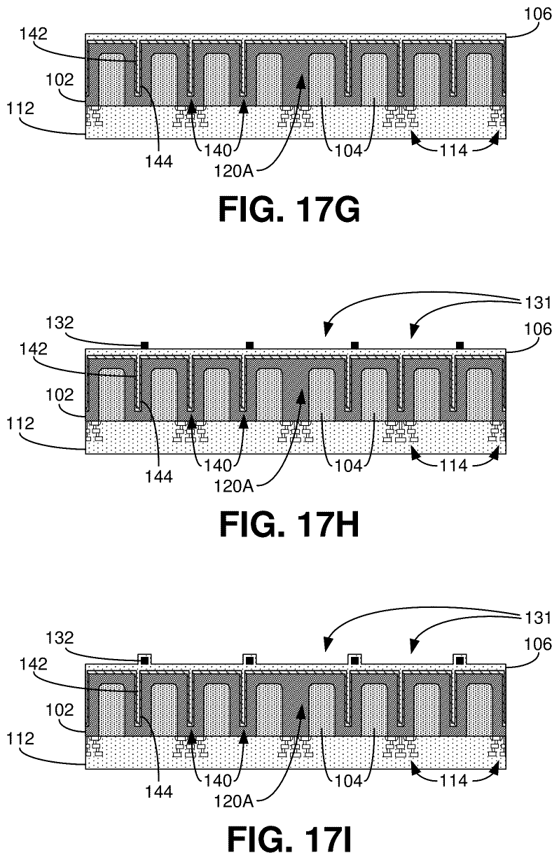

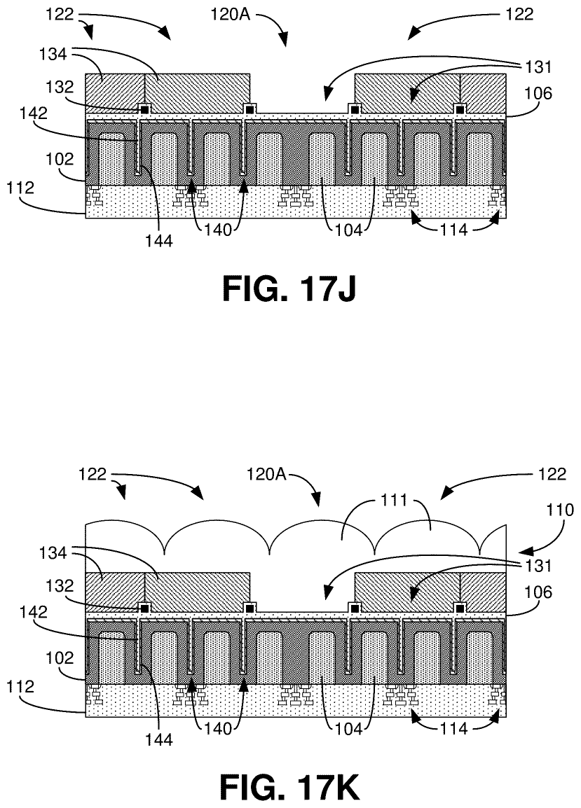

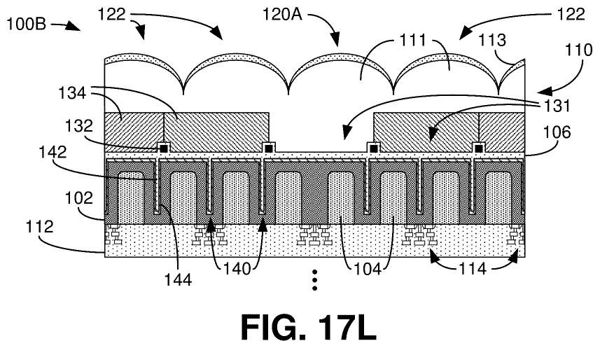

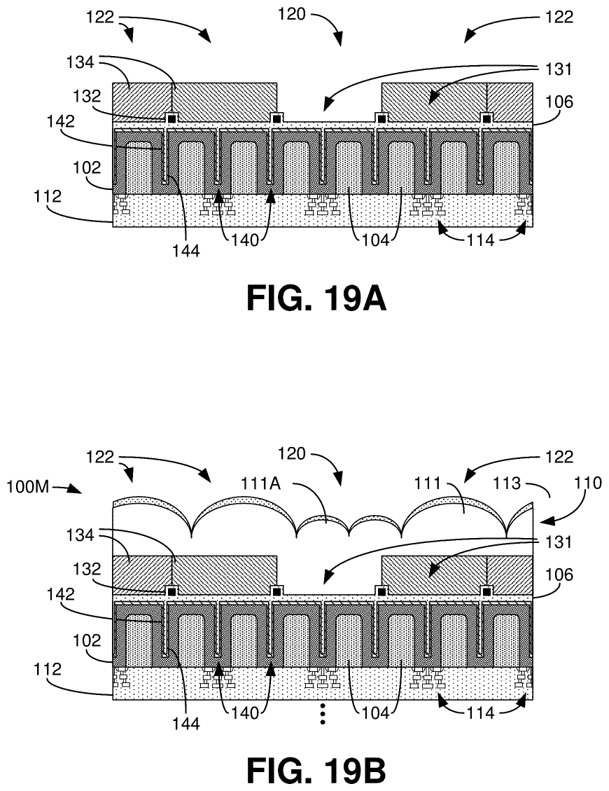

FIGS. 1A through 1D illustrate a plan view, a cross-sectional view, an alternative cross-sectional view, and an additional cross-sectional view, respectively, of some embodiments of an integrated circuit (IC) device 100A employing an isolation structure 140 providing reduced crosstalk for half-shield PDAF, according to the present disclosure. More specifically, FIG. 1A is a plan view of IC device 100A that corresponds with the cross-sectional view of FIG. 1B, in which the components of the various layers of IC device 100A that are associated with each pixel are stacked vertically. However, in other embodiments, these same components may be skewed laterally from layer to layer, as shown in the cross-sectional view of FIG. 1C. For example, in some embodiments, the chief ray angle (CRA) associated with each pixel may vary based on the position of the pixel within a pixel array in the IC device 100A. More specifically, pixels at or near the center of the array may have a chief ray angle of approximately zero degrees, resulting in the components of the pixel being stacked substantially vertically, as depicted in FIGS. 1A and 1B. In contrast, pixels near the edge or corner of the array may have a significant chief ray angle that necessitates skewing of the components of such pixels toward the center of the array, as depicted in FIG. 1C. In some examples, this component skew may exacerbate potential crosstalk between a phase detection pixel and an imaging pixel. While various embodiments shown in FIGS. 2 through 12, FIGS. 13A and 13B, and FIGS. 14 through 16 depict the vertically-aligned case, the same embodiments discussed below may also apply to the skewed case, such as those shown in FIG. 2C, FIG. 13C, FIGS. 17A through 17L, and FIGS. 19A and 19B.

As shown in the cross-sectional views of FIGS. 1B, 1C, and 1D, a substrate 102 may include a number of photosensitive regions 104 that form photodetectors (PDs) (e.g., photodiodes or the like). Photosensitive regions 104 may be formed (e.g., doped or implanted) in substrate 102. In some embodiments, as illustrated in FIGS. 1A through 1D, four photosensitive regions 104 are included in each pixel. However, one or more photosensitive regions 104 may be employed in each pixel in other embodiments.

In some embodiments, one or more photosensitive regions 104 may be arranged to form a corresponding photosensitive region group. Further, each photosensitive region group may be associated with a phase detection (e.g., HSPD) pixel 120A or an image pixel 122. In embodiments depicted in FIGS. 1A through 1D, as well as others discussed below, each phase detection pixel 120A and image pixel 122 may be associated with a photosensitive region group that includes four photosensitive regions 104 (e.g., in a two-by-two arrangement). As illustrated in FIG. 1A, image pixels 122 may be arranged in a particular pattern (e.g., in a larger two-by-two arrangement) to facilitate accurate color imaging. Further, phase detection pixels 120A may be distributed in a periodic manner among image pixels 122. In some embodiments, phase detection pixels 120A may be disposed in pairs. For example, a first phase detection pixel 120A may correspond with a half-shield (HS) 130 covering a first (e.g., left-half or lower-half) pair of photosensitive regions 104 associated with first phase detection pixel 120A (e.g., as depicted in FIG. 1A). Further, a second phase detection pixel 120A may correspond with a half-shield 130 covering a second (e.g., right-half or upper-half) pair of photosensitive regions 104 associated with second phase detection pixel 120A. However, other arrangements of image pixels 122 and phase detection pixels 120A other than that shown in FIG. 1A are also possible.

Adjacent to substrate 102 (e.g., at a first side of substrate 102) may be a circuit dielectric layer 112 that includes conductive structures 114 (e.g., metal (copper (Cu)), alloy, or other conductive material) to form sensor circuits that are coupled with photosensitive regions 104 of substrate 102 (e.g., to transfer the charge generated by photons impacting photosensitive regions 104, to reset the associated photodetectors, and so on). Circuit dielectric layer 112 may include one or more dielectric materials, including, but not limited to, silicon oxide (SiOₓ) (e.g., silicon oxide (SiO₂)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like. Additional layers (e.g., additional substrates, circuit dielectric layers, and/or the like) may be disposed under circuit dielectric layer 112 in some embodiments, but such layers are not discussed further herein to simplify the following discussion.

As shown in FIGS. 1A through 1D, an isolation structure 140 may be disposed within substrate 102. In some embodiments, isolation structure 140 includes portions (e.g., walls) that extend from a second side of substrate 102 at least partway toward the first side of substrate 102. In some embodiments, isolation structure 140 is configured to laterally isolate (e.g., in the plan view) each photosensitive region 104 of each image pixel 122 from neighboring other photosensitive regions 104, as shown in the plan view of FIG. 1A.

Also, in some embodiments, isolation structure 140 is configured differently in each of one or more phase detection pixels 120A than in each of image pixels 122 in the plan view of IC device 100A. An example of such a configuration is represented by the absence of walls for isolation structure 140 in the photosensitive region group of phase detection pixel 120A. In some embodiments, such configurations for isolation structure 140 for the phase detection pixels 120A represent a distinguishing feature among the various embodiments of FIGS. 1A through 1D and FIGS. 2-12, as described in greater detail below.

In some embodiments, as shown in FIGS. 1A through 1D, isolation structure 140 may include a first (e.g., outer) dielectric layer 144 and a second (e.g., inner) dielectric layer 142. In some embodiments, first dielectric layer 144 may include, but is not limited to, silicon-oxide-aluminum (SiOAl), aluminum oxide (AlO), hafnium oxide (HfO), tantalum-oxide-silicon (TaOSi), doped polycrystalline silicon, another dielectric material, and/or the like. Also, in some embodiments, second dielectric layer 142 may include, but is not limited to, silicon oxide (SiOₓ) (e.g., silicon dioxide (SiO₂)), another dielectric material, and/or the like. Further, in some embodiments, an additional air gap layer may be disposed in second dielectric layer 142. For example, in some embodiments, both first dielectric layer 144 and second dielectric layer 142 may be conformally deposited on substrate 102 and in one or more trenches in substrate 102, leaving an air gap defined by second dielectric layer 142 within one or more of the trenches. In some embodiments, a subsequent dielectric layer (e.g., at least a portion of sensor dielectric layer 106) may close an upper end of the air gap.

Other materials and numbers of layers may be employed for isolation structure 140 in other embodiments. Further, in some embodiments, isolation structure 140 may be fashioned as a backside deep trench isolation (BDTI) structure, as shown in FIGS. 1B through 1D. Additionally, in some embodiments (not shown explicitly in FIGS. 1B through 1D), such a BDTI structure may be complemented with a frontside DTI (FDTI) structure extending from the first (e.g., lower) side of substrate 102 and extending toward a lower end of the BDTI structure.

In some embodiments, a sensor dielectric layer 106 may be disposed over substrate 102. In some embodiments, sensor dielectric layer 106 may include one or more dielectric materials, such as those listed above in conjunction with circuit dielectric layer 112 or isolation structure 140. For example, sensor dielectric layer 106 may include first dielectric layer 144 and second dielectric layer 142 (e.g., as discussed above in connection with isolation structure 140), or may include one or more other dielectric materials (e.g., materials included in circuit dielectric layer 112) in other embodiments. In some embodiments, the sensor dielectric layer 106 may continuously extend from over the substrate 102 to be a part of the isolation structure 140 within trenches within the substrate 102. Further, in some embodiments, second dielectric layer 106 may include or serve as a passivation layer and/or an anti-reflective coating. For example, first dielectric layer 144 may serve as an anti-reflective coating, while second dielectric layer 142 may serve as a passivation layer.

Continuing with FIGS. 1A through 1D, a grid structure 132 may be disposed over sensor dielectric layer 106. In some embodiments, grid structure 132 may include a plurality of grid segments 133 that extend laterally over sensor dielectric layer 106. Also, in some embodiments, grid structure 132 may circumscribe the photosensitive region group of each phase detection pixel 120A and image pixel 122, as shown to best effect in FIG. 1A. Consequently, grid structure 132 may provide an opening 131 through which light may be received by photosensitive regions 104 of each phase detection pixel 120A and image pixel 122. In some embodiments, grid structure 132 may include, but is not limited to, a metallic material (e.g., tungsten (W)) or other conductive material (e.g., titanium nitride (TiN), possibly serving as a barrier layer), a dielectric material (e.g., silicon oxide (SiOₓ)), or the like. Also, in some embodiments, grid structure 132 may be covered or sealed with the same or similar material as that employed for sensor dielectric layer 106 (e.g., silicon dioxide (SiO₂)). In some embodiments, grid structure 132 may be a material that substantially reflects light.

In some embodiments, also disposed over sensor dielectric layer 106 (e.g., aligned with grid structure 132 in the cross-sectional view of FIG. 1D) in each phase detection pixel 120A may be a half-shield 130, as mentioned above. In some embodiments, half-shield 130 may cover approximately half, or slightly less than half, or slightly more than half, of phase detection pixel 120A, thus approximately covering half (e.g., two) of photosensitive regions 104 of phase detection pixel 120A for phase detection purposes. While FIG. 1A depicts half-shield 130 covering a left half of phase detection pixel 120A, half-shield 130 may cover a right half, lower half, or upper half in other embodiments. In some embodiment, half-shield 130 may be contiguous with at least some surrounding grid segments 133 of grid structure 132. Further, in some embodiments, half-shield 130 may include the same material as grid structure 132, as described above, or may include other materials, such as conductive or dielectric materials.

In some embodiments, an optical filter element 134 may be disposed over photosensitive regions 104 of each image pixel 122 (e.g., on sensor dielectric layer 106). More specifically, each optical filter element 134 may be an element that passes a particular bandwidth (e.g., color) of light to underlying photosensitive regions 104 while blocking others. In some embodiments, the passed bandwidth or color may be red, blue, or green. More particularly, image pixels 122 may generally be organized in sets of two-by-two, with one red, one blue, and two green optical filter elements 134. Further, in some embodiments, no optical filter element 134 may be disposed over each phase detection pixel 120A (e.g., as shown in FIGS. 1B through 1D), or a clear optical filter element 134 (e.g., an element that passes most optical bandwidths, an element that passes radiation having wavelengths between approximately 380 nanometers (nm) and approximately 780 nm, etc.) may be disposed over each phase detection pixel 120A. In some embodiments, each optical filter element 134 may include, but is not limited to, a pigment material, a dye material, or the like disposed on sensor dielectric layer 106.

Additionally, as depicted in FIGS. 1B through 1D, an optical lens layer 110 (e.g., including a plurality of lens portions 111, such as microlenses) may be disposed over optical filter elements 134 and sensor dielectric layer 106. More specifically, in some embodiments, optical lens layer 110 may be disposed on optical filter element 134 of each image pixel 122, and may extend further toward substrate 102 onto sensor dielectric layer 106 corresponding to each phase detection pixel 120A. Moreover, in some embodiments, each lens portion 111 may be disposed over photosensitive regions 104 of a corresponding image pixel 122 or phase detection pixel 120A. In some embodiments, optical lens layer 110 may include, but is not limited to, silicon dioxide (SiO₂) or silica-based glass, another type of glass, another substantially transparent material, or the like. Further, while each lens portion 111 of optical lens layer 110 is presented as a microlens in FIGS. 1B through 1D, other types of lenses (e.g., Fresnel-type lenses) may be employed in other embodiments, but are not specifically discussed herein.

Further, in some embodiments, an anti-reflective coating (ARC) 113 may be disposed over optical lens layer 110. In some embodiments, ARC 113 may be fabricated using titanium nitride (TiN), silicon nitride (SiN), silicon oxynitride (SiON), tantalum pentoxide (Ta₂O₅), and/or another anti-reflective material that allows light to pass therethrough.

As shown in FIG. 1C, in some embodiments, light 152 passing through ARC 113, optical lens layer 110, and sensor dielectric layer 106 of phase detection pixel 120A may not encounter a wall or other element of isolation structure 140 before being absorbed by a photosensitive region 104, thus reducing the possibility of at least some of light 152 being redirected toward a neighboring image pixel 122.

As discussed above, embodiments of FIGS. 1A through 1D include isolation structure 140 that provides a reduced or modified configuration of isolation structure 140 for the photosensitive region group of one or more phase detection pixels 120A. In some embodiments, the modified structure may be an absence of walls or other elements of isolation structure 140 within grid structure 132 in a plan view of IC device 100A. Similarly, FIGS. 2 through 12 illustrate plan views of some additional embodiments of an IC device employing an isolation structure (e.g., a reduced or modified isolation structure 140) providing reduced crosstalk for half-shield PDAF, according to the present disclosure. Other portions of the IC devices depicted in FIGS. 2 through 12 may have the same or similar structures or elements as those described above in conjunction with IC device 100A of FIGS. 1A through 1D.

For example, FIG. 2 depicts an IC device 100B with a photosensitive region group of a phase detection pixel 120B in which isolation structure 140 includes a single wall 252 spanning the photosensitive region group and separating at least one photosensitive region 104 from another photosensitive region 104 of the photosensitive region group. More specifically, single wall 252 may extend across a central region of phase detection pixel 120B (e.g., under, and along an edge of, half-shield 130). In some embodiments, single wall 252 may be separated from opposing sides of phase detection pixel 120B by substantially equal distances.

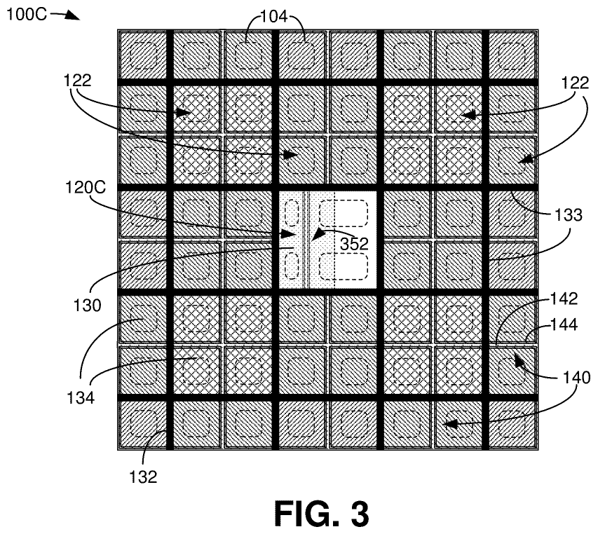

Similarly, FIG. 3 depicts an IC device 100C with a photosensitive region group of a phase detection pixel 120C in which isolation structure 140 includes a single linear wall 352 spanning the photosensitive region group and separating at least one photosensitive region 104 from another photosensitive region 104 of the photosensitive region group. More specifically, single linear wall 352 may extend across a central region of half-shield 130 in the plan view of FIG. 3. In such embodiments, a width of one or more photosensitive regions 104 may be increased or decreased (e.g., as illustrated in FIG. 3) such that single linear wall 352 may not intersect photosensitive regions 104 of the photosensitive region group. In some embodiments, single wall 252 may be separated from a first side of phase detection pixel 120C by a larger distance than an opposing second side of phase detection pixel 120C.

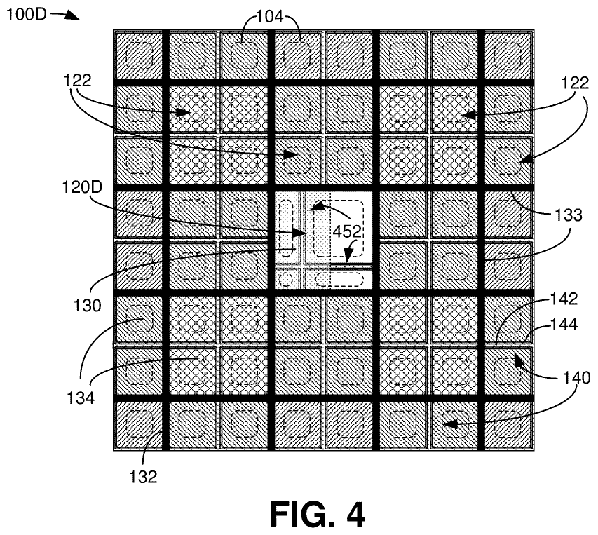

FIG. 4 depicts an IC device 100D with a photosensitive region group of a phase detection pixel 120D in which isolation structure 140 includes first and second linear walls 452 that intersect. More specifically, first linear wall 452 spans the photosensitive region group in a first lateral direction in the plan view of IC device 100D, and second linear wall 452 spans the photosensitive region group in a second lateral direction perpendicular to the first lateral direction in the plan view of IC device 100D. In some embodiments, first and second linear walls 452 may intersect in a quadrant region (e.g., the lower left region in the example of FIG. 4) in the plan view of IC device 100D. Further, in some embodiments, the quadrant region at which first and second linear walls 452 intersect may be disposed under half-shield 130, as shown in FIG. 4. Also, in some embodiments, a width of one or more photosensitive regions 104 may be increased or decreased (e.g., as illustrated in FIG. 3) such that first and second linear walls 452 may not intersect photosensitive regions 104 of the photosensitive region group.

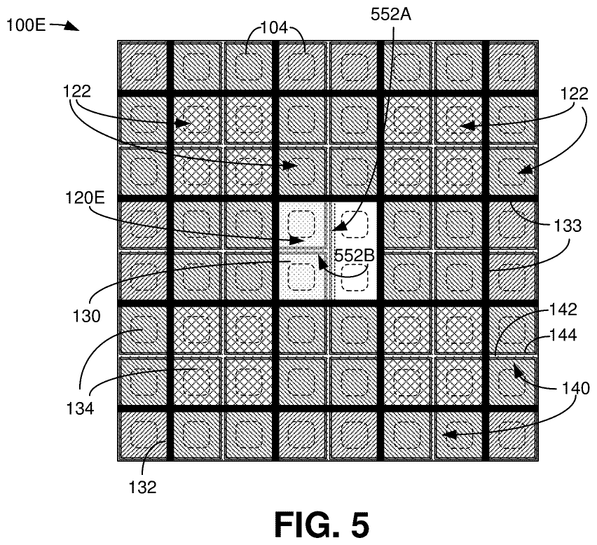

FIG. 5 depicts an IC device 100E with a photosensitive region group of phase detection pixel 120E in which isolation structure 140 includes a first linear wall 552A and a second linear wall 552B that intersect. More specifically, first linear wall 552A spans the photosensitive region group in a first lateral direction in the plan view of IC device 100E, and second linear wall 552B extends from first linear wall 552A in a second lateral direction perpendicular to the first lateral direction in the plan view of IC device 100E to a periphery of the photosensitive region group. In some embodiments, first linear wall 552A and second linear wall 552B may separate two of photosensitive regions 104 of the photosensitive region group from each other and other photosensitive regions 104 of the photosensitive region group in the plan view of IC device 100E. Also, in some embodiments (e.g., as depicted in FIG. 5), first linear wall 552A and second linear wall 552B may be disposed completely under half-shield 130.

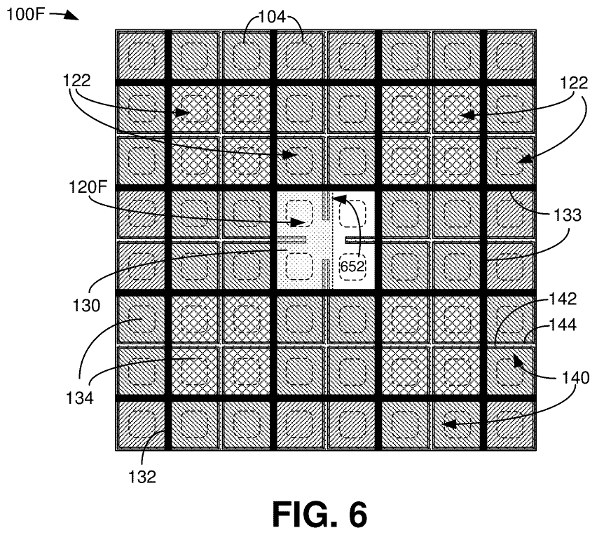

FIG. 6 depicts an IC device 100F with a photosensitive region group of phase detection pixel 120F in which isolation structure 140 includes four individual walls 652, each of which extend from a corresponding wall of isolation structure 140 at a periphery of the photosensitive region group partway toward a central region of the photosensitive region group in a plan view of IC device 100F. In some embodiments (e.g., as depicted in FIG. 6), three individual walls 652 may be disposed completely under half-shield 130, and one individual wall 652 may be completely uncovered by half-shield 130. Further, in some embodiments, each individual wall 652 may or may not be the same length as other individual walls 652 in the plan view of IC device 100F.

While embodiments illustrated in FIGS. 1A through 1D and FIGS. 2-6 involve the use of a left-half half-shield 130 in the plan views provided, these same embodiments may also be employed with a right-half half-shield 130, in which each of such embodiments may appear as a left-right mirror image or a 180-degree-rotated image to those depicted in FIGS. 1A through 1D and FIGS. 2 through 6. Such mirror-image or rotated-image embodiments may appear on the same IC device, as HSPD mechanisms may employ pairs of phase detection pixels 120A through 120F, where each pair may include a phase detection pixel 120A through 120F with a left-half half-shield 130 and a phase detection pixel 120A through 120F with a right-half half-shield 130.

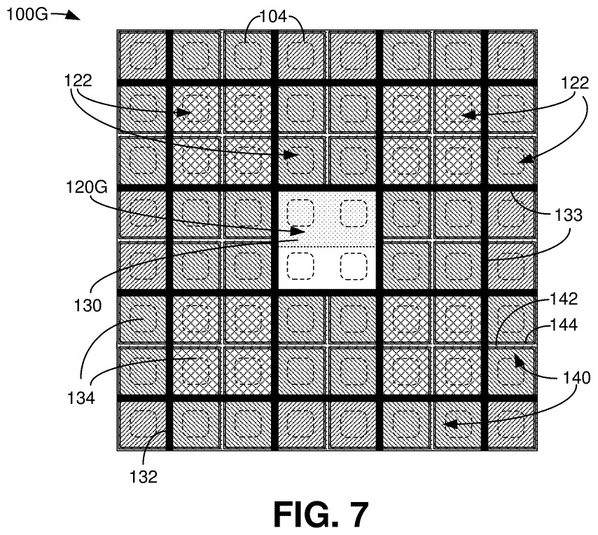

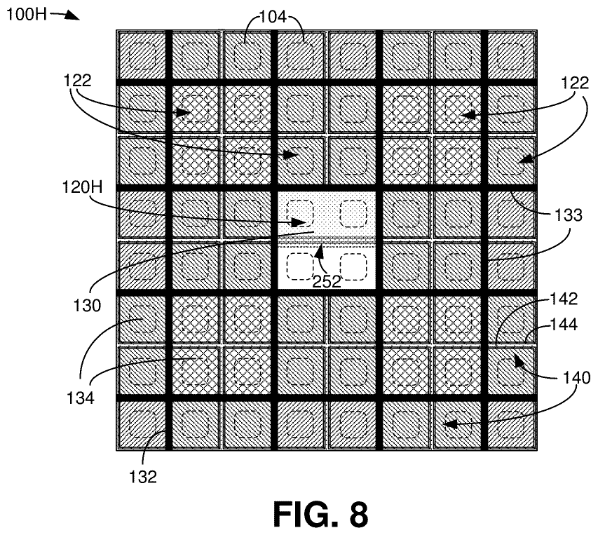

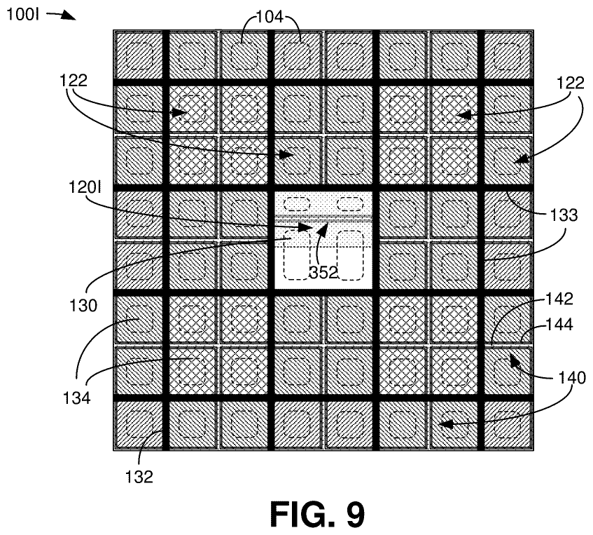

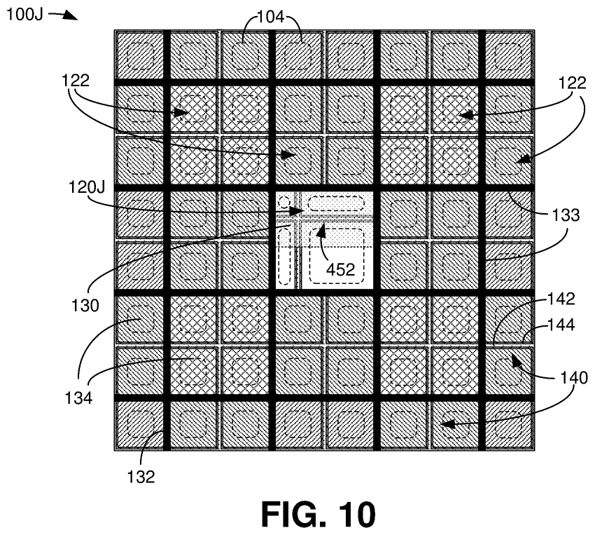

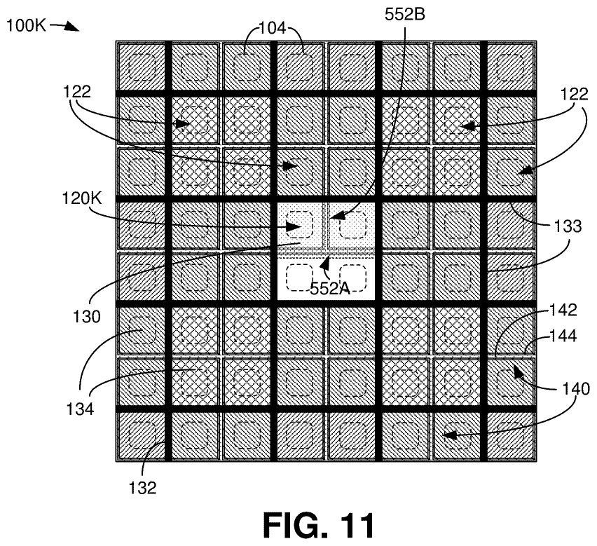

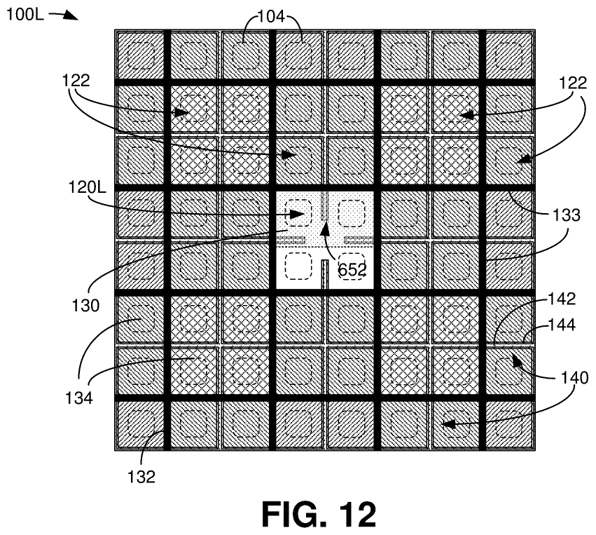

Further, FIGS. 7 through 12 illustrate some embodiments associated with those of FIGS. 1A through 1D and FIGS. 2 through 6, but while employing a upper-half half-shield 130 instead of a left-half half-shield 130. More specifically, the embodiments of FIG. 7 (IC device 100G with a phase detection pixel 120G), FIG. 8 (IC device 100H with a phase detection pixel 120H), FIG. 9 (IC device 100I with a phase detection pixel 120I), FIG. 10 (IC device 100J with a phase detection pixel 120J), FIG. 11 (IC device 100K with a phase detection pixel 120K), and FIG. 12 (IC device 100L with a phase detection pixel 120L), correspond to the embodiments of FIGS. 1A through 1D, FIG. 2, FIG. 3, FIG. 4, FIG. 5, and FIG. 6, respectively. Further, each of the portions of isolation structure 140 associated with phase detection pixel 120G through 120L of FIGS. 7 through 12 are rotated clockwise 90 degrees relative to those of FIGS. 1A through 1D, FIG. 2, FIG. 3, FIG. 4, FIG. 5, and FIG. 6 to align with the upper-half half-shield 130 being employed therein.

Moreover, while embodiments illustrated in FIGS. 7 through 12 involve the use of an upper-half half-shield 130 in the plan views provided, these same embodiments may also be employed with a lower-half half-shield 130, in which each of such embodiments may appear as a upper-lower mirror image or a 180-degree-rotated image to those depicted in FIGS. 7 through 12. Such mirror-image or rotated-image embodiments may appear on the same IC device, as HSPD mechanisms may employ pairs of phase detection pixels 120G through 120L, where each pair may include a phase detection pixel with an upper-half half-shield 130 and a phase detection pixel with a lower-half half-shield 130. Further, in some embodiments, a mixture of upper-half and lower-half half-shields 130 and left-half and right-half half-shields 130 may be appropriate depending on the chief ray angle (CRA) of the corresponding phase detection pixels 120G through 120L (e.g., to maximize the reduction in crosstalk caused by the associated phase detection pixel).

Aside from, or in addition to, the various embodiments of FIGS. 1A through 1D and FIGS. 2 through 12, in which a reduced or modified portion of isolation structure 140 is incorporated in phase detection pixels 120A through 120L, modifications may be made to portions of optical lens layer 110 relative to the phase detection pixels to reduce crosstalk while maintaining an acceptable QE profile. For example, FIGS. 13A through 13C illustrate a plan view, a vertically-oriented cross-sectional view, and a skewed cross-sectional view, respectively, of some embodiments of an IC device 100M employing an optical lens layer 110 providing reduced crosstalk for half-shield PDAF, according to the present disclosure. In some embodiments, optical lens layer 110 may include first curved surfaces disposed directly over image pixels 122 and second curved surfaces disposed over phase detection pixel 120, in a cross-sectional view. The first curved surfaces have a larger arc length than the second curved surfaces. More specifically, while individual lens portions 111 of optical lens layer 110 disposed over corresponding image pixels 122 may remain spherical, as depicted in FIGS. 1 through 12, each phase detection pixel 120 may be associated with two elliptical lens portions 111A. Further, in some embodiments, each elliptical lens portion 111A may be disposed over a corresponding pair of photosensitive regions 104 of phase detection pixel 120. Moreover, in some embodiments, each elliptical lens portion 111A may extend perpendicularly to half-shield 130 such that approximately half of each elliptical lens portion 111A is disposed over left-half half-shield 130. Consequently, as shown in FIG. 13C, light 152 may be directed by each elliptical lens portion 111A such that reflection at the side of substrate 102 adjacent circuit dielectric layer 112 may be directed in a manner that reduces or minimizes crosstalk with adjacent image pixels 122.

FIG. 13D illustrates a cross-sectional view of some embodiments of an IC device 100N employing both isolation structure 140 and optical lens layer 110 providing reduced crosstalk for half-shield PDAF, according to the present disclosure. For example, isolation structure 140 may be as shown in FIG. 1C, in which no walls of isolation structure 140 reside within phase detection pixel 120, and optical lens layer 110 may include both spherical lens portions 111 and elliptical lens portions 111A. Further, in some embodiments, any isolation structure 140 of FIGS. 1A through 1C and FIGS. 2 through 12 may be employed with optical lens layer 110 of FIGS. 13A through 13C and FIGS. 14-16 in the same IC device.

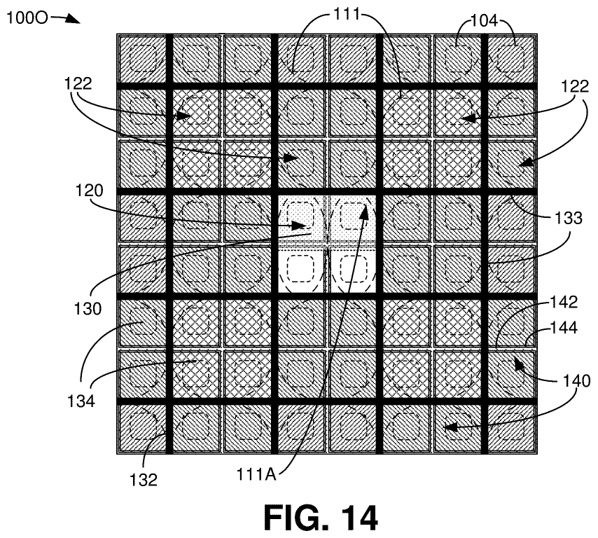

While FIGS. 13A through 13D depict the use of a left-half half-shield 130, FIG. 14 illustrates a plan view of some additional embodiments of an IC device 100O employing an optical lens layer 110 in which a pair of elliptical lens portions 111A are disposed over an upper-half half-shield 130, where each elliptical lens portion 111A is disposed over a corresponding pair of photosensitive regions 104. In some embodiments, elliptical lens portions 111A are rotated 90 degrees clockwise in the plan view of FIG. 14 relative to those illustrated in FIG. 13A. Additionally, in some embodiments, elliptical lens portions 111A may be employed with a lower-half half-shield 130, including in some embodiments where both upper-half and lower-half half-shields 130 are employed in an IC device.

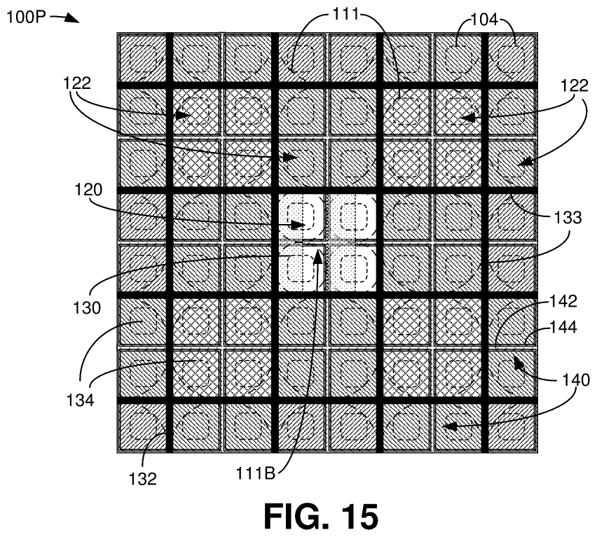

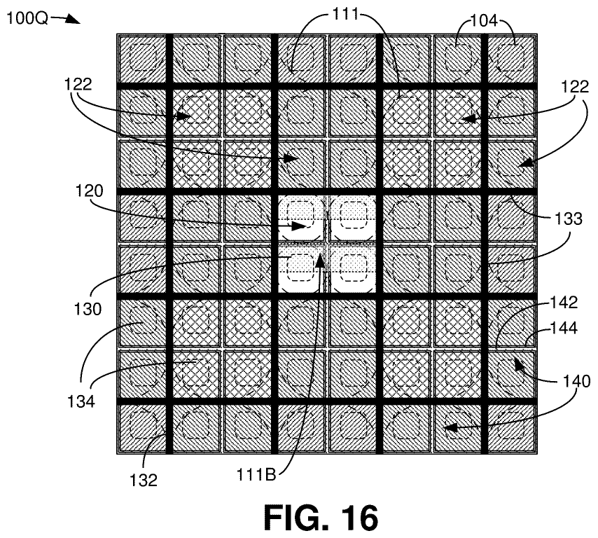

FIG. 15 illustrates embodiments of an IC device 100P, in which four spherical lens portions 111B are disposed over corresponding photosensitive regions 104 of phase detection pixel 120. Each spherical lens portion 111B, in some embodiments, may have a diameter approximately half of the diameter of each spherical lens portion 111 associated with an image pixel 122. Further, in some embodiments, phase detection pixel 120 may have two separate left-half half-shields 130 associated therewith, one for each pair of spherical lens portions 111B. Similarly, FIG. 16 illustrates embodiments of an IC device 100Q in which two upper-half half-shields 130 are employed with four spherical lens portions 111B, in a manner similar to that illustrated in FIG. 15. Additionally, in some embodiments, spherical lens portions 111B may be employed with two lower-half half-shields 130, including in some embodiments where both upper-half and lower-half half-shields 130 are employed in an IC device. In additional, combinations of upper-half, lower-half, left-half, and right-half half-shields 130 and associated spherical lens portions 111B may be employed within the same IC device in some embodiments.

FIGS. 17A through 17L illustrate cross-sectional views of some embodiments of an IC device (e.g., IC device 100A, as shown in the cross-sectional view of FIG. 1C) employing a reduced or modified portion of an isolation structure (e.g., isolation structure 140 of FIG. 1C) at various stages of manufacture, according to the present disclosure. Although FIGS. 17A through 17L are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part.

For example, FIG. 17A illustrates a substrate 102 (e.g., a semiconductor substrate, such as a silicon (Si) substrate or the like). In some embodiments, substrate 102 may serve as a substrate for a backside portion of IC device 100A, including a sensor dielectric layer 106, a grid structure 132, and so on. In addition, substrate 102 may also serve as a substrate for a frontside portion of IC device 100A, such as circuit dielectric layer 112 and associated conductive structures 114 of FIG. 1C.

FIG. 17B illustrates the forming (e.g., implantation, doping, or the like) of photosensitive regions 104 via a frontside surface of substrate 102 to form corresponding photodetectors (e.g., PN photodiodes, PIN photodiodes, or the like) in conjunction with surrounding areas of substrate 102. In some embodiments, substrate 102 may be a p-type substrate and photosensitive regions 104 may be n-doped regions. In other embodiments, photosensitive regions 104 may be employed to form other types of photodetectors in conjunction with substrate 102.

FIG. 17C illustrates the forming (e.g., by way of iterative lithography, etching, and deposition) of one or more circuit dielectric layers 112 that include a plurality of conductive structures 114 to form circuits electrically coupled with photosensitive regions 104. Conductive structures 114 may include, but are not limited to, a metal (e.g., copper (Cu), an alloy, another conductive material, or the like. Circuit dielectric layers 112, in some embodiments, may include, but are not limited to, silicon oxide (SiOₓ) (e.g., silicon oxide (SiO₂)), silicon nitride (SiN), silicon carbide (SiC), carbon-doped silicon dioxide, silicon oxynitride, borosilicate glass (BSG), phosphorus silicate glass (PSG), borophosphosilicate (BPSG), fluorosilicate glass (FSG), undoped silicate glass (USG), a porous dielectric material, or the like, as discussed above.

FIG. 17D illustrates the inversion (e.g., flipping) of the subassembly of FIG. 17C to facilitate access to a backside of substrate 102 opposite the frontside of substrate 102 to enable subsequent processing as described below with respect to FIGS. 17E through 17L.

FIG. 17E illustrates the removal (e.g., by way of lithography and etching) of portions of substrate 102 to form trenches 1710 in which isolation structure 140 is to be formed. In some embodiments, trenches 1710 may extend a majority of the way toward the frontside of substrate 102. Further, trenches 1710 may laterally surround each photosensitive region 104 of the photosensitive region group of each image pixel 122 while providing a reduced or modified configuration for trenches 1710 within the photosensitive region group associated with a phase detection pixel 120A (e.g., by omitting trenches 1710 associated with phase detection pixel 120A), as described above.

FIG. 17F illustrates the conformal forming (e.g., conformal deposition) of first dielectric layer 144 for isolation structure 140 into trenches 1710 and on substrate 102. As described above, in some embodiments, first dielectric layer 144 may include, but is not limited to, silicon-oxide-aluminum (SiOAl), aluminum oxide (AlO), hafnium oxide (HfO), tantalum-oxide-silicon (TaOSi), doped polycrystalline silicon, another high-κ dielectric material, another dielectric material, or the like.

FIG. 17G illustrates the forming (e.g., deposition) of second dielectric layer 142 in trenches 1710 and over first dielectric layer 144. As discussed above, in some embodiments, second dielectric layer 142 may include, but is not limited to, silicon oxide (SiOₓ) (e.g., silicon dioxide (SiO₂)), another dielectric material, and/or the like. Further, in some embodiments, second dielectric layer 142, possibly in conjunction with first dielectric layer 144, may form sensor dielectric layer 106 over substrate 102. Thereafter, in some embodiments, an upper surface of sensor dielectric layer 106 may be planarized (e.g., via chemical-mechanical planarization (CMP)).

FIG. 17H illustrates the forming (e.g., by deposition, photolithography, and etching) of grid structure 132 on sensor dielectric layer 106 to surround the photosensitive region group for each phase detection pixel 120 and image pixel 122 in the plan view. As a result, grid structure 132 may provide an opening 131 through which light may be received by photosensitive regions 104 of each phase detection pixel 120 and image pixel 122. In some embodiments, as discussed earlier, grid structure 132 may include, but is not limited to, a metallic material (e.g., tungsten (W)) or other conductive material (e.g., titanium nitride (TiN), possibly serving as a barrier layer), a dielectric material (e.g., silicon oxide (SiOₓ)), or the like.

FIG. 17I illustrates the forming (e.g., conformal deposition) of additional dielectric material (e.g., the same material employed for sensor dielectric layer 106, such as silicon dioxide (SiO₂), or another dielectric material) to cover or seal grid structure 132.

FIG. 17J illustrates the forming of optical filter elements 134 over grid structure 132 and sensor dielectric layer 106. In some embodiments, each optical filter element 134 may possess a particular color associated with a corresponding image pixel 122. As described above, in some embodiments, each optical filter element 134 may allow light associated with a particular color (e.g., red, green, or blue) to pass therethrough, thus filtering other colors. In some embodiments, the forming of optical filter elements 134 may include, for each type or color of optical filter element 134, applying a color composition layer, selectively patterning (e.g., exposing to ultraviolet (UV) light) the color composition layer, and removing unexposed areas of the color composition layer to form a pattern of optical filter elements 134 having the desired color.

FIG. 17K illustrates the forming (e.g., by way of deposition, patterning, and reflowing) of an optical lens layer 110 on optical filter elements 134 (e.g., for image pixels 122) and sensor dielectric layer 106 (e.g., for phase detection pixels 120), where optical lens layer 110 provides a lens portion 111 (e.g., a spherical microlens or the like) for each corresponding image pixel 122 and phase detection pixel 120) to focus received light towards photosensitive regions 104 corresponding with the associated pixel. In some embodiments, the forming of lens portions 111 may include forming a photosensitive layer of substantially transparent material (e.g., a polymer, an oxide (e.g., SiO₂), or other substantially transparent material), patterning the photosensitive layer, and then reflowing the patterned photosensitive layer (e.g., at some predetermined temperature) to form lens portions 111.

FIG. 17L illustrates the forming (e.g., deposition) of an ARC 113 on optical lens layer 110. In some embodiments, ARC 113 may include, but is not be limited to, titanium nitride (TiN), silicon nitride (SiN), silicon oxynitride (SiON), tantalum pentoxide (Ta₂O₅), and/or another anti-reflective material that allows light to pass therethrough, as discussed above.

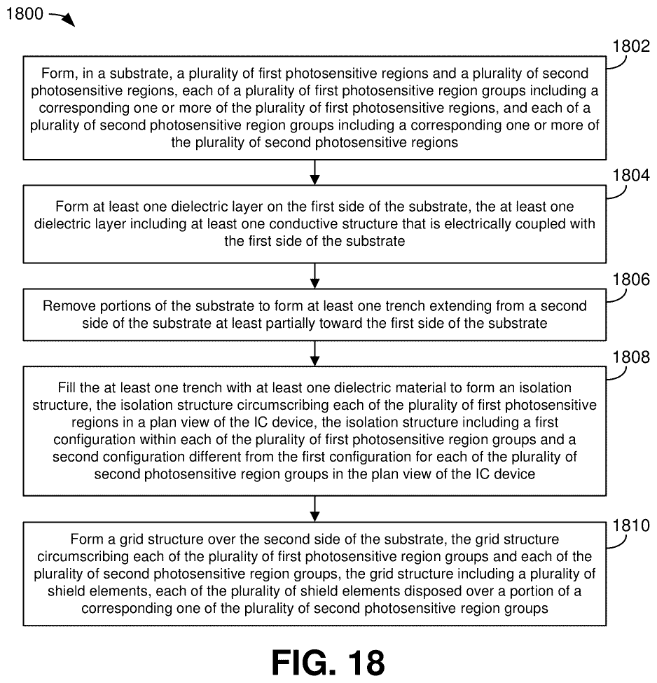

FIG. 18 illustrates a block diagram of some embodiments of a methodology 1800 of forming an IC device (e.g., IC device 100A of FIG. 1C) employing an isolation structure providing reduced crosstalk for half-shield PDAF, according to the present disclosure. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

For example, at Act 1802, a plurality of first photosensitive regions (e.g., photosensitive regions 104 of FIG. 17B) is formed in a substrate (e.g., substrate 102 of FIGS. 17A and 17B) by way of a first side of the substrate. In some embodiments, each of a plurality of first photosensitive region groups includes a corresponding one or more of the plurality of first photosensitive regions. Also, a plurality of second photosensitive regions (e.g., photosensitive regions 104 of FIG. 17B) is formed in the substrate by way of the first side of the substrate. In some embodiments, each of a plurality of second photosensitive region groups includes a corresponding one or more of the plurality of second photosensitive regions. In some embodiments, each of the plurality of first photosensitive region groups may be associated with a corresponding one of a plurality of image pixels (e.g., photosensitive regions 104 of each image pixel 122 of FIGS. 1A through 1D), and each of the plurality of second photosensitive region groups may be associated with a corresponding one of a plurality of phase detection pixels (e.g., photosensitive regions 104 of each phase detection pixel 120 of FIGS. 1A through 1D). FIGS. 17A and 17B illustrate cross-sectional views of some embodiments corresponding to Act 1802.

At Act 1804, at least one dielectric layer (e.g., circuit dielectric layer 112 of FIG. 17C) is formed on the first side of the substrate. In some embodiments, the at least one dielectric layer may include at least one conductive structure (e.g., conductive structure 114 of FIG. 17C) that is electrically coupled with the first side of the substrate. FIG. 17C illustrates a cross-sectional view of some embodiments corresponding to Act 1804.

At Act 1806, portions of the substrate are removed to form at least one trench (e.g., trenches 1710 of FIG. 17E) extending from a second side of the substrate at least partially toward the first side of the substrate. FIGS. 17D and 17E illustrate cross-sectional views of some embodiments corresponding to Act 1806.

At Act 1808, the at least one trench is filled with at least one dielectric material (e.g., first dielectric layer 144 of FIG. 17F and second dielectric layer 142 of FIG. 17G) to form an isolation structure (e.g., isolation structure 140 of FIG. 17G). In some embodiments, the isolation structure may circumscribe each of the plurality of first photosensitive regions in a plan view of the IC device. Also, in some embodiments, the isolation structure may include a first configuration for each of the plurality of first photosensitive region groups and a second configuration different from the first configuration for each of the plurality of second photosensitive region groups in the plan view of the IC device (e.g., a lack of walls between photosensitive regions 104 of phase detection pixel 120A of FIG. 17G). FIGS. 17F and 17G illustrate cross-sectional views of some embodiments corresponding to Act 1808.

At Act 1810, a grid structure (e.g., grid structure 132 of FIG. 17H) is formed over the second side of the substrate. In some embodiments, the grid structure may circumscribe each of the plurality of first photosensitive region groups and each of the plurality of second photosensitive region groups. Also, the grid structure may include a plurality of shield elements (e.g., half-shield 130 of FIGS. 1A and 1D). Further, each of the plurality of shield elements may be disposed over a portion of a corresponding one of the plurality of second photosensitive region groups. FIG. 17H illustrates a cross-sectional view of some embodiments corresponding to Act 1810.

FIGS. 19A and 19B illustrate cross-sectional views of some embodiments of an IC device (e.g., IC device 100M, as shown in the cross-sectional view of FIG. 13C) employing an optical lens layer (e.g., optical lens layer 110 of FIG. 13C) at various stages of manufacture, according to the present disclosure. Although FIGS. 19A and 19B are described as a series of acts, it will be appreciated that these acts are not limiting in that the order of the acts within each series can be altered in other embodiments, and the methods disclosed are also applicable to other structures. In other embodiments, some acts that are illustrated and/or described may be omitted in whole or in part.

For example, FIG. 19A illustrates a subassembly including substrate 102 with photosensitive regions 104 for image pixels 122 and phase detection pixels 120, circuit dielectric layer 112 with conductive structures 114, isolation structure 140 in substrate 102 that may include first dielectric layer 144 and second dielectric layer 142, sensor dielectric layer 106, grid structure 132 defining multiple openings 131, and optical filter elements 134 for image pixels 122. Fabrication of the subassembly is at least similar to that described above in conjunction with FIGS. 17A through 17J, with the exception of the configuration of isolation structure 140 within phase detection pixel 120, which may match the configuration of isolation structure 140 within image pixels 122. More specifically, in some embodiments, as shown in FIG. 19A, isolation structure 140 surrounds each photosensitive region 104 within both phase detection pixel 120 and image pixels 122.

FIG. 19B illustrates the forming (e.g., by way of deposition, patterning, and reflowing) of an optical lens layer 110 on optical filter elements 134 (e.g., for image pixels 122) and sensor dielectric layer 106 (e.g., for phase detection pixels 120), where optical lens layer 110 provides a lens portion 111 (e.g., a spherical microlens or the like) for each corresponding image pixel 122, and provides a plurality of lens portions 111A (e.g., elliptical microlenses or the like) for each corresponding phase detection pixel 120 to focus received light towards photosensitive regions 104 corresponding with the associated pixel. In some embodiments, the forming of lens portions 111 and 111A may be as described above in connection with FIG. 17K. Thereafter, in some embodiments, an ARC 113 is formed on optical lens layer 110, as described in detail above in conjunction with FIG. 17L.

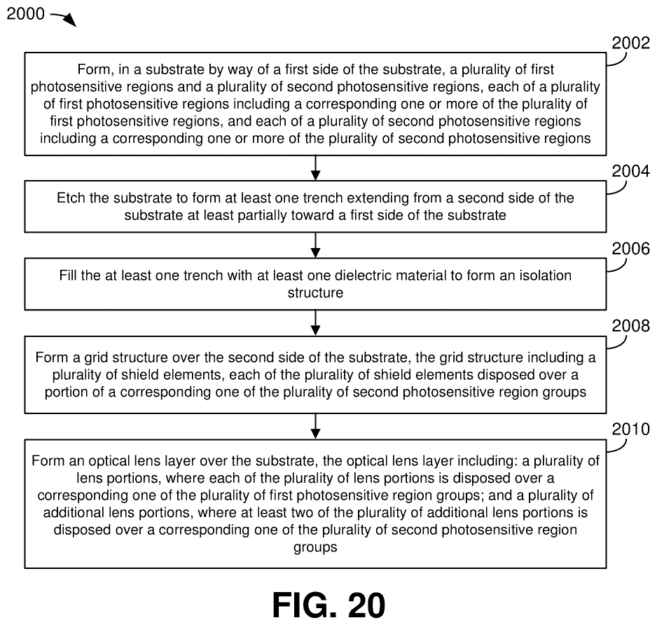

FIG. 20 illustrates a block diagram of some embodiments of a methodology 2000 of forming an IC device (e.g., IC device 100M of FIG. 13C) employing an optical lens layer providing reduced crosstalk for half-shield PDAF, according to the present disclosure.

For example, at Act 2002, a plurality of first photosensitive regions (e.g., photosensitive regions 104 of FIG. 17B) is formed in a substrate (e.g., substrate 102 of FIGS. 17A and 17B) by way of a first side of the substrate. In some embodiments, each of a plurality of first photosensitive region groups includes a corresponding one or more of the plurality of first photosensitive regions. Also, a plurality of second photosensitive regions (e.g., photosensitive regions 104 of FIG. 17B) is formed in the substrate by way of the first side of the substrate. In some embodiments, a plurality of second photosensitive region groups includes a corresponding one or more of the plurality of second photosensitive regions. Each of the plurality of first photosensitive region groups may be associated with a corresponding one of a plurality of image pixels (e.g., photosensitive regions 104 of each image pixel 122 of FIGS. 13A through 13C), and each of the plurality of second photosensitive region groups may be associated with a corresponding one of a plurality of phase detection pixels (e.g., photosensitive regions 104 of each phase detection pixel 120 of FIGS. 13A through 13C). FIGS. 17A and 17B illustrate cross-sectional views of some embodiments corresponding to Act 2002.

At Act 2004, the substrate is etched to form at least one trench (e.g., trenches 1710 of FIG. 17E) extending from a second side of the substrate at least partially toward the first side of the substrate. FIGS. 17D and 17E illustrate cross-sectional views of some embodiments corresponding to Act 2004.

At Act 2006, the at least one trench is filled with at least one dielectric material (e.g., first dielectric layer 144 of FIG. 17F and second dielectric layer 142 of FIG. 17G) to form an isolation structure (e.g., isolation structure 140 of FIG. 17G). In some embodiments, the isolation structure may circumscribe each of the plurality of first photosensitive regions and each of the plurality of second photosensitive regions in a plan view of the IC device. FIGS. 17F and 17G, augmented by the isolation structure 140 of FIG. 19A, illustrate cross-sectional views of some embodiments corresponding to Act 2006.

At Act 2008, a grid structure (e.g., grid structure 132 of FIG. 17H) is formed over the first side of the substrate. In some embodiments, the grid structure may circumscribe each of the plurality of first photosensitive region groups and each of the plurality of second photosensitive region groups. Also, the grid structure may include a plurality of shield elements (e.g., half-shield 130 of FIG. 13A). Further, each of the plurality of shield elements may be disposed over a portion of a corresponding one of the plurality of second photosensitive region groups. FIG. 17H, augmented by the isolation structure 140 of FIG. 19A, illustrates a cross-sectional view of some embodiments corresponding to Act 2008.

At Act 2010, an optical lens layer (e.g., optical lens layer 110 of FIG. 19B) is formed over the plurality of optical filter elements and the substrate. In some embodiments, the optical lens layer may include a plurality of lens portions (e.g., lens portions 111 of FIG. 19B) and a plurality of additional lens portions (e.g., lens portions 111A of FIG. 19B). In some embodiments, each of the plurality of lens portions may be disposed over a corresponding one of the plurality of first photosensitive region groups. Further, in some embodiments, at least two of the plurality of additional lens portions may be disposed over a corresponding one of the plurality of second photosensitive region groups. FIG. 19B illustrates a cross-sectional view of some embodiments corresponding to Act 2010.

In some embodiments, the present disclosure provides an IC device, including: a substrate including: a plurality of first photosensitive regions, where each of a plurality of first photosensitive region groups includes a corresponding one or more of the plurality of first photosensitive regions, and where each of the plurality of first photosensitive region groups is associated with a corresponding one of a plurality of image pixels; and a plurality of second photosensitive regions, where each of a plurality of second photosensitive region groups includes a corresponding one or more of the plurality of second photosensitive regions, and where each of the plurality of second photosensitive region groups is associated with a corresponding one of a plurality of phase detection pixels; an isolation structure extending at least partially toward a first side of the substrate from a second side of the substrate, the isolation structure circumscribing each of the plurality of first photosensitive regions in a plan view of the IC device, the isolation structure including a first configuration for each of the plurality of image pixels and a second configuration different from the first configuration for each of the plurality of phase detection pixels in the plan view of the IC device; and a grid structure disposed over the first side of the substrate, the grid structure circumscribing each of the plurality of first photosensitive region groups and each of the plurality of second photosensitive region groups, the grid structure including a plurality of shield elements, each of the plurality of shield elements disposed over a portion of a corresponding one of the plurality of second photosensitive region groups.

In some embodiments, the present disclosure provides a method of fabricating an IC device. The method includes: forming, in a substrate, a plurality of first photosensitive regions and a plurality of second photosensitive regions, each of a plurality of first photosensitive region groups including a corresponding one or more of the plurality of first photosensitive regions, and each of a plurality of second photosensitive region groups including a corresponding one or more of the plurality of second photosensitive regions; forming at least one dielectric layer on a first side of the substrate, the at least one dielectric layer including at least one conductive structure that is electrically coupled with the first side of the substrate; removing portions of the substrate to form at least one trench extending from a second side of the substrate at least partially toward the first side of the substrate; filling the at least one trench with at least one dielectric material to form an isolation structure, the isolation structure circumscribing each of the plurality of first photosensitive regions in a plan view of the IC device, the isolation structure including a first configuration for each of the plurality of first photosensitive region groups and a second configuration different from the first configuration for each of the plurality of second photosensitive region groups in the plan view of the IC device; and forming a grid structure over the second side of the substrate, the grid structure circumscribing each of the plurality of first photosensitive region groups and each of the plurality of second photosensitive region groups, the grid structure including a plurality of shield elements, each of the plurality of shield elements disposed over a portion of a corresponding one of the plurality of second photosensitive region groups.

In some embodiments, the present disclosure provides another method of fabricating an IC device. The method includes: forming, in a substrate, a plurality of first photosensitive regions and a plurality of second photosensitive regions, each of a plurality of first photosensitive region groups including a corresponding one or more of the plurality of first photosensitive regions, and each of a plurality of second photosensitive region groups including a corresponding one or more of the plurality of second photosensitive regions; etching the substrate to form at least one trench extending from a second side of the substrate at least partially toward a first side of the substrate; filling the at least one trench with at least one dielectric material to form an isolation structure; forming a grid structure over the second side of the substrate, the grid structure including a plurality of shield elements, each of the plurality of shield elements disposed over a portion of a corresponding one of the plurality of second photosensitive region groups; and forming an optical lens layer over the substrate, the optical lens layer including: a plurality of lens portions, where each of the plurality of lens portions is disposed over a corresponding one of the plurality of first photosensitive region groups; and a plurality of additional lens portions, where at least two of the plurality of additional lens portions is disposed over a corresponding one of the plurality of second photosensitive region groups.

It will be appreciated that in this written description, as well as in the claims below, the terms “first”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a substrate comprising:
a plurality of first photosensitive regions, wherein each of a plurality of first photosensitive region groups comprises a corresponding one or more of the plurality of first photosensitive regions, and wherein each of the plurality of first photosensitive region groups is associated with a corresponding one of a plurality of image pixels; and
a plurality of second photosensitive regions, wherein each of a plurality of second photosensitive region groups comprises a corresponding one or more of the plurality of second photosensitive regions, and wherein each of the plurality of second photosensitive region groups is associated with a corresponding one of a plurality of phase detection pixels;
an isolation structure extending at least partially toward a first side of the substrate from a second side of the substrate, the isolation structure circumscribing each of the plurality of first photosensitive regions in a plan view of the IC device, the isolation structure comprising a first configuration for each of the plurality of image pixels and a second configuration different from the first configuration for each of the plurality of phase detection pixels in the plan view of the IC device; and
a grid structure disposed over the first side of the substrate, the grid structure circumscribing each of the plurality of first photosensitive region groups and each of the plurality of second photosensitive region groups, the grid structure comprising a plurality of shield elements, each of the plurality of shield elements disposed over a portion of a corresponding one of the plurality of second photosensitive region groups.

2. The IC device of claim 1, wherein, for a phase detection pixel of the plurality of phase detection pixels, the isolation structure comprises an opening over an entirety of the phase detection pixel in the plan view of the IC device.

3. The IC device of claim 1, wherein, for a phase detection pixel of the plurality of phase detection pixels, the isolation structure comprises a single linear wall spanning the phase detection pixel and separating at least one of the second photosensitive regions of the phase detection pixel from another one of the second photosensitive regions of the phase detection pixel in the plan view of the IC device.

4. The IC device of claim 3, wherein the single linear wall is disposed at a central region of the shield element of the phase detection pixel in the plan view of the IC device.

5. The IC device of claim 3, wherein the single linear wall is disposed along an edge of the shield element of the phase detection pixel in the plan view of the IC device.

6. The IC device of claim 1, wherein, for a phase detection pixel of the plurality of phase detection pixels, the isolation structure comprises:
a first linear wall spanning the phase detection pixel in a first lateral direction in the plan view of the IC device; and
a second linear wall spanning the phase detection pixel in a second lateral direction perpendicular to the first lateral direction in the plan view of the IC device, wherein the first linear wall and the second linear wall intersect in a quadrant region of the phase detection pixel in the plan view of the IC device.

7. The IC device of claim 6, wherein the quadrant region is disposed under the shield element of the phase detection pixel.

8. The IC device of claim 1, wherein, for a phase detection pixel of the plurality of phase detection pixels, the isolation structure comprises:
a first linear wall spanning the phase detection pixel in a first lateral direction in the plan view of the IC device; and
a second linear wall extending from the first linear wall in a second lateral direction perpendicular to the first lateral direction in the plan view of the IC device to a periphery of the phase detection pixel, wherein the first linear wall and the second linear wall separate two of the second photosensitive regions of the phase detection pixel from each other and others of the second photosensitive regions of the phase detection pixel in the plan view of the IC device.

9. The IC device of claim 8, wherein the first linear wall and the second linear wall are disposed completely under the shield element of the phase detection pixel.

10. The IC device of claim 1, wherein, for a phase detection pixel of the plurality of phase detection pixels, the isolation structure comprises:
four individual walls, each of the four individual walls extending partway from a corresponding wall of the isolation structure at a periphery of the phase detection pixel toward a central region of the phase detection pixel in a plan view of the IC device.

11. The IC device of claim 1, further comprising:
a plurality of optical filter elements disposed over the grid structure, each of the plurality of optical filter elements disposed over a corresponding one of the plurality of image pixels; and
an optical lens layer disposed over the plurality of optical filter elements and the substrate, the optical lens layer comprising:
a plurality of spherical lens portions, each of the plurality of spherical lens portions disposed over a corresponding one of the plurality of image pixels; and
a plurality of elliptical lens portions, each of the plurality of elliptical lens portions disposed over a corresponding half of one of the plurality of phase detection pixels.

12. The IC device of claim 1, further comprising:
a plurality of optical filter elements disposed over the grid structure, each of the plurality of optical filter elements disposed over a corresponding one of the plurality of image pixels; and
an optical lens layer disposed over the plurality of optical filter elements and the substrate, the optical lens layer comprising:
a plurality of first spherical lens portions, each of the plurality of first spherical lens portions disposed over a corresponding one of the plurality of image pixels; and
a plurality of second spherical lens portions, each of the plurality of second spherical lens portions disposed over a corresponding second photosensitive region of one of the plurality of phase detection pixels.

13. A method of fabricating an integrated circuit (IC) device, the method comprising:
forming, in a substrate, a plurality of first photosensitive regions and a plurality of second photosensitive regions, each of a plurality of first photosensitive region groups comprising a corresponding one or more of the plurality of first photosensitive regions, and each of a plurality of second photosensitive region groups comprising a corresponding one or more of the plurality of second photosensitive regions;
forming at least one dielectric layer on a first side of the substrate, the at least one dielectric layer including at least one conductive structure that is electrically coupled with the first side of the substrate;
removing portions of the substrate to form at least one trench extending from a second side of the substrate at least partially toward the first side of the substrate;
filling the at least one trench with at least one dielectric material to form an isolation structure, the isolation structure circumscribing each of the plurality of first photosensitive regions in a plan view of the IC device, the isolation structure comprising a first configuration within each of the plurality of first photosensitive region groups and a second configuration different from the first configuration for each of the plurality of second photosensitive region groups in the plan view of the IC device; and
forming a grid structure over the second side of the substrate, the grid structure circumscribing each of the plurality of first photosensitive region groups and each of the plurality of second photosensitive region groups, the grid structure comprising a plurality of shield elements, each of the plurality of shield elements disposed over a portion of a corresponding one of the plurality of second photosensitive region groups.

14. The method of claim 13, wherein, for a second photosensitive region group of the plurality of second photosensitive region groups, the isolation structure comprises an opening over an entirety of the second photosensitive region group in the plan view of the IC device.

15. The method of claim 13, wherein, for a second photosensitive region group of the plurality of second photosensitive region groups, the isolation structure comprises a single linear wall spanning the second photosensitive region group and separating at least one of the second photosensitive regions of the second photosensitive region group from another one of the second photosensitive regions of the second photosensitive region group in the plan view of the IC device.

16. The method of claim 13, wherein, for a second photosensitive region group of the plurality of second photosensitive region groups, the isolation structure comprises two intersecting linear walls separating the second photosensitive regions of the second photosensitive region group from each other in the plan view of the IC device.

17. The method of claim 13, further comprising:
forming a plurality of optical filter elements over the grid structure, each of the plurality of optical filter elements disposed over a corresponding one of the plurality of first photosensitive region groups; and
forming an optical lens layer over the plurality of optical filter elements and the substrate, the optical lens layer comprising a plurality of spherical lens portions, each of the plurality of spherical lens portions disposed over a corresponding one of the plurality of first photosensitive region groups or a corresponding one of the plurality of second photosensitive regions.

18. A method of fabricating an integrated circuit (IC) device, the method comprising:
forming, in a substrate, a plurality of first photosensitive regions and a plurality of second photosensitive regions, each of a plurality of first photosensitive region groups comprising a corresponding one or more of the plurality of first photosensitive regions, and each of a plurality of second photosensitive region groups comprising a corresponding one or more of the plurality of second photosensitive regions;
etching the substrate to form at least one trench extending from a second side of the substrate at least partially toward a first side of the substrate;
filling the at least one trench with at least one dielectric material to form an isolation structure;
forming a grid structure over the second side of the substrate, the grid structure comprising a plurality of shield elements, each of the plurality of shield elements disposed over a portion of a corresponding one of the plurality of second photosensitive region groups; and
forming an optical lens layer over the substrate, the optical lens layer comprising:
a plurality of lens portions, wherein each of the plurality of lens portions is disposed over a corresponding one of the plurality of first photosensitive region groups; and
a plurality of additional lens portions, wherein at least two of the plurality of additional lens portions is disposed over a corresponding one of the plurality of second photosensitive region groups.

19. The method of claim 18, wherein the plurality of lens portions comprises spherical lens portions and the at least two of the plurality of additional lens portions comprises two elliptical lens portions, and each of the two elliptical lens portions is disposed over a corresponding half of the corresponding one of the plurality of second photosensitive region groups.

20. The method of claim 18, wherein the at least two of the plurality of additional lens portions comprises four spherical lens portions, and each of the four spherical lens portions is disposed over a corresponding quarter of the corresponding one of the plurality of second photosensitive region groups.
